(19) United States
(12) Patent Application Publication
(10) Pub. No.: US 2007/0147449 A1
(43) Pub. Date: Jun. 28, 2007

(54) Semiconductor laser device and manufacturing method thereof

(75) Inventors: Yasuyuki Bessho, Uji (JP); Yasuhiko Nomura, Osaka (JP)

Correspondence Address: NDQ&M WATCHSTONE LLP, 1300 EYE STREET, NW, SUITE 1000 WEST TOWER, WASHINGTON, DC, 20005, US

(73) Assignee: Sanyo Electric Co., Ltd., Moriguchi (JP)

(21) Appl. No.: 11/642,933

(22) Filed: Dec. 21, 2006

(30) Foreign Application Priority Data
Dec. 27, 2005 (JP) JP2005-374222
Aug. 31, 2006 (JP) JP2006-235673

(51) Int. Cl. H01S 5/00; H01S 3/04

(52) U.S. Cl. 372/36; 372/49.01

(57) ABSTRACT

A nitride semiconductor laser device 20 has nitride semiconductor laser element 5 with dielectric layer 5b composed of SiO₂ formed on light emitting face 5a. The nitride semiconductor laser element 5 is air-tightly sealed within package 1. The atmosphere within the package contains oxygen with less than 5000 ppm water and more than 5% oxygen. By controlling the atmosphere within package 1, less deterioration of outputs and less deterioration of reliability is achieved due to changes in the dielectric layer formed at a facet of the semiconductor laser.

### CROSS REFERENCE TO RELATED APPLICATIONS

This application claims priority based on 35 USC 119 from prior Japanese Patent Application No. P2005-374222 filed on Dec. 27, 2005 and Japanese Patent Application No. P2006-235673 filed on Aug. 31, 2006, the entire contents of which are incorporated herein by reference.

### BACKGROUND OF THE INVENTION

1. Field of the Invention

The present invention relates to a semiconductor laser device and its manufacturing method. In particular, the present invention relates to a semiconductor laser device having a package in which a semiconductor laser element is air-tightly sealed and the manufacturing method thereof.

2. Description of Related Art

A semiconductor laser device having a semiconductor laser element air-tightly sealed in a package has been known. For example, Japanese Laid-Open Publication No. 2005-209801 describes a nitride semiconductor laser device having a nitride semiconductor laser element mounted on a stem (support), and a cap made of a nonconductive material is joined to the stem such that the cap covers the nitride semiconductor laser element.

In the nitride semiconductor laser element described in Japanese Laid-Open publication No. 2005-209801, a coating layer is formed for adjusting reflectivity of the end surfaces of the semiconductor laser element. In general, a semiconductor laser element has coating layers formed at the front facet (laser light emitting face) and at the rear facet for controlling reflectivity and for protecting the facets. As a material for such facet coating layers, dielectrics such as SiO₂ and SiN are used.

However, in the nitride semiconductor laser device described in Japanese Laid-Open publication No. 2005-209801, no consideration is given regarding the atmosphere and water concentration within the package, and the materials for the facet coating layers. Therefore, there have been problems in that depending on the atmosphere and water concentration within the package and the materials for the facet coating layers, the facet coating layers change their properties and the output characteristics of the nitride semiconductor laser element deteriorate.

### SUMMARY OF THE INVENTION

The present invention alleviates the above described problems. One object of the present invention is to provide a semiconductor laser device that can prevent deterioration of outputs and reliability due to the change of properties of the dielectric layers formed at the facets of the semiconductor laser element, and also to provide a manufacturing method for such a semiconductor laser device.

To achieve the above objects, one aspect of a semiconductor laser device according to an embodiment comprises a semiconductor laser element having an oxide dielectric layer formed at least on a laser light emitting face, and a package within which the semiconductor laser element is air-tightly sealed. The atmosphere within the package is an oxygen-containing atmosphere having water concentration of less than 5,000 ppm.

By forming a oxide dielectric layer at least on the laser light emitting face, sealing the semiconductor laser element air-tightly within the package, and setting the atmosphere within the package an oxygen-containing atmosphere having water concentration of less than 5,000 ppm, detachment of oxygen from the oxide dielectric layer due to low oxygen concentration in the package atmosphere can be suppressed. Therefore, water absorption and water adsorption by the dielectric layer caused at an accelerated rate by such detachment of oxygen from the dielectric layer can be suppressed. By controlling the atmosphere within the package to a water concentration of less than 5,000 ppm, water absorption and water adsorption by the dielectric layer can be even more effectively suppressed. As a result, deterioration of characteristics of the semiconductor laser element can be prevented and reliability of the semiconductor laser device can increase because detachment of oxygen from the dielectric layer and water absorption and water adsorption by the dielectric layer can be repressed.

Another aspect of a semiconductor laser device according to an embodiment comprises a semiconductor laser element having an oxide dielectric layer formed not on a laser light emitting surface, but on a rear facet that is at the opposite side from the laser light emitting face, and a package within which the semiconductor laser element is air-tightly sealed. The atmosphere within the package is an oxygen-containing atmosphere having water concentration of less than 5,000 ppm.

The oxygen concentration within the oxygen-containing atmosphere is preferably more than 5%. Preferably, the package includes a support for supporting the semiconductor laser element and a cap joined to the support for air-tightly sealing the semiconductor laser element therewithin, and oxidation resistant layers are formed on the surface of the support and the interior surface of the cap. Preferably, a welding joint part is formed at the junction between the cap and the support. The semiconductor laser element is preferably a nitride semiconductor laser element.

One aspect of a method of manufacturing a semiconductor laser device according to an embodiment comprises forming an oxide dielectric layer at least on a laser light emitting face of a semiconductor laser element, mounting the semiconductor laser element onto a support, exposing the support on which the semiconductor laser element is mounted with an ultraviolet light, and then air-tightly sealing the semiconductor laser element with a cap in an oxygen-containing atmosphere having water concentration of less than 5,000 ppm and oxygen concentration of more than 5%.

By forming an oxide dielectric layer at least on the laser light emitting face of a semiconductor laser element, air-tightly sealing the semiconductor laser element within the package, and setting the package atmosphere to be an oxygen-containing atmosphere, disadvantages such as detachment of oxygen from the oxide dielectric layer due to low oxygen concentration of the atmosphere within the package can be suppressed in the above manufacturing method of a semiconductor laser device. Therefore, water absorption and water adsorption by the dielectric layer caused at an accelerated rate by the detachment of oxygen from the dielectric layer can be suppressed. By setting the atmosphere within the package to have water concentration of less than 5,000 ppm, water absorption and water adsorption by the dielectric layer can be even more effectively suppressed. Also, by exposing the support on which the semiconductor laser element is mounted with an ultraviolet light, even when extraneous substances are attached on the semiconductor laser element, such extraneous substances can be removed by photodecomposition by the ultraviolet exposure. Therefore, moisture and organic substances contained in the extraneous substances can be prevented from vaporizing into the atmosphere within the package, which can prevent increase of water concentration within the package. As a result, deterioration of characteristics of the semiconductor laser element can be prevented and reliability of the semiconductor laser device can increase because detachment of oxygen from the dielectric layer, and water absorption and water adsorption by the dielectric layer can be suppressed.

Preferably, the above manufacturing method of a semiconductor laser device further includes cleaning at least the laser light emitting face of the semiconductor laser element by plasma prior to forming the oxide dielectric layer.

Another aspect of the method of manufacturing a semiconductor laser device according to an embodiment comprises forming an oxide dielectric layer not on the laser light emitting face of a semiconductor laser element but on a rear facet that is at the opposite side from the laser light emitting face, mounting the semiconductor laser element onto a support, exposing the support on which the semiconductor laser element is mounted with ultraviolet light, and then air-tightly sealing the semiconductor laser element with a cap in an oxygen-containing atmosphere having water concentration of less than 5,000 ppm and oxygen concentration of more than 5%.

Preferably, the above manufacturing method of a semiconductor laser device further includes cleaning the rear facet of the semiconductor laser element at the opposite side from the laser light emitting face by plasma prior to forming the oxide dielectric layer.

The above process of cleaning by plasma is preferably conducted in an inert gas atmosphere, for example in a noble gas or a nitrogen gas.

### BRIEF DESCRIPTION OF THE DRAWINGS

FIG. 1 is a perspective view of a representative structure of a nitride semiconductor laser device according to one embodiment of the present invention.

FIG. 2 is a cross sectional view taken along line 100-100 of FIG. 1.

FIG. 3 is a cross sectional view showing the semiconductor laser element structure of the nitride semiconductor laser device according to the embodiment of FIG. 1.

FIGS. 4 to 9 are explanatory views showing a manufacturing method of the nitride semiconductor laser device according to the embodiment of FIG. 1.

FIG. 10 is a correlation diagram showing the relation between operating current of the nitride semiconductor laser device according to example 1 that corresponds to the embodiment of FIG. 1 and elapsed time.

FIG. 11 is a correlation diagram showing the relation between operating current of the nitride semiconductor laser device according to example 2 that corresponds to the embodiment of FIG. 1 and elapsed time.

FIG. 12 is a correlation diagram showing the relation between operating current of the nitride semiconductor laser device according to comparative example 1 and elapsed time.

FIG. 13 is a correlation diagram showing the relation between operating current of the nitride semiconductor laser device according to comparative example 2 and elapsed time.

FIG. 14 is a correlation diagram showing the relation between water concentration of the nitride semiconductor laser device and the rate of current rise.

FIG. 15 is a correlation diagram showing the relation between operating current of the nitride semiconductor laser device according to comparative example 3 and elapsed time.

FIG. 16 is a graph showing an example of the relation between a recording rate and a light output of a semiconductor laser element when a semiconductor laser element that outputs blue-violet laser light is used as a light source.

FIG. 17 is a graph showing the relation between current-carrying time and a COD level in the nitride semiconductor laser devices according to examples 3 to 5 having water concentration of 5000 ppm atmosphere within the package.

FIG. 18 is a graph showing the relation between a light output of the nitride semiconductor laser element and the rate of current rise after 100 hours of carrying current in the nitride semiconductor laser devices according to examples 3 to 5 having water concentration of 5000 ppm atmosphere within the package.

FIG. 19 is a graph showing the relation between current-carrying time and a COD level in the nitride semiconductor laser devices according to comparative examples 4 to 6 having water concentration of 5500 ppm atmosphere within the package.

FIG. 20 is a graph showing the relation between a light output of the nitride semiconductor laser element and the rate of current rise after 100 hours of carrying current in the nitride semiconductor laser devices according to comparative examples 4 to 6 having water concentration of 5500 ppm atmosphere within the package.

### DETAILED DESCRIPTION OF EMBODIMENTS

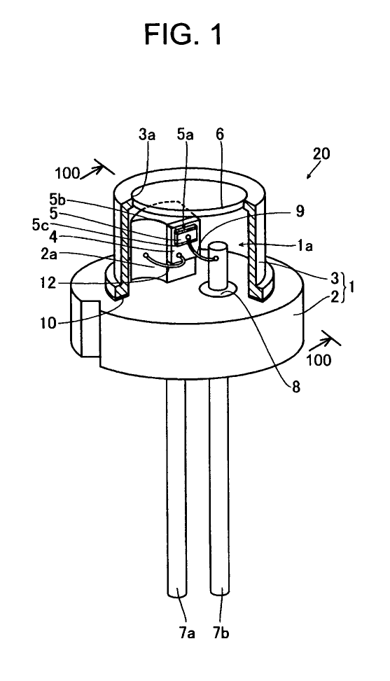

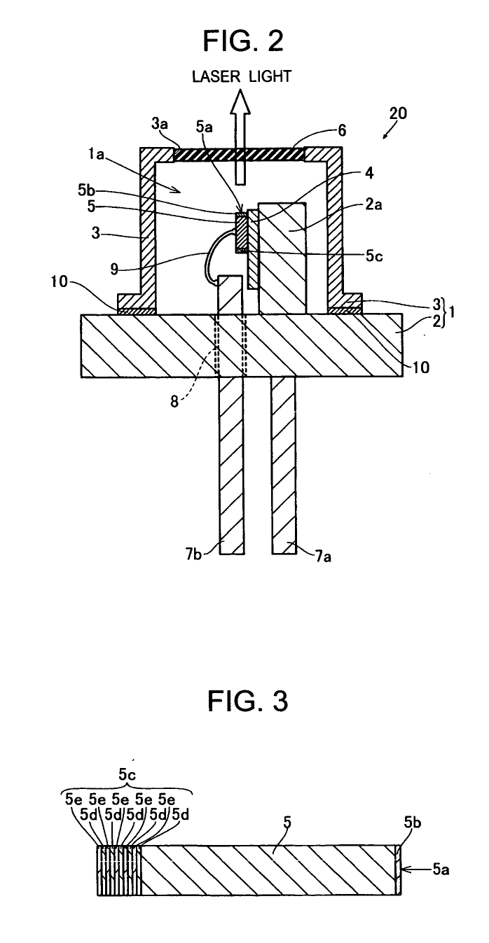

Embodiments of the present invention will be described with reference to the accompanying drawings. FIG. 1 is a perspective view of a nitride semiconductor laser device structure according to one embodiment of the present invention, and FIG. 2 is a cross sectional view taken along line 100-100 of FIG. 1. FIG. 3 is a cross sectional view showing the semiconductor laser element structure of the nitride semiconductor laser device according to the embodiment of FIG. 1 Referring to FIGS. 1 to 3, the structure of nitride semiconductor laser device 20 according to one embodiment will be described. In this embodiment, nitride semiconductor laser device 20 has nitride semiconductor laser element 5 that outputs a blue-violet laser beam with a wavelength of 405 nm, as one example of the semiconductor laser device of the present invention.

As shown in FIG. 1, nitride semiconductor laser device 20 of this embodiment has nitride semiconductor laser element 5, which is mounted within package 1 composed of iron stem 2 and cap 3 made of kovar (54% Fe-29% Ni-17% Co alloy). As shown in FIGS. 1 and 2, nitride semiconductor laser device 20 of this embodiment includes heat release part 2a made of copper which is formed integrally with iron stem 2. Heat sink (submount) 4 made of AlN is mounted at heat release part 2a, and semiconductor laser element 5 is mounted on heat sink 4. Nitride semiconductor laser element 5 is positioned with light emitting face (facet of the cavity on the light emitting side) 5a opposing cap glass 6 as described below. Two leads 7a and 7b are fixed to stem 2, and one of the leads 7b is electrically isolated from stem 2 by insulation ring 8. Lead 7a is fixed to stem 2 such that lead 7a is electrically connected to one electrode of the nitride semiconductor laser element 5 by connecting the heat release part 2a and an electrode (not shown) on the heat sink 4 by wire 12. One end of lead 7b protrudes onto the area 1a side from an upper face of stem 2. Further, leads 7a and 7b are fixed to maintain air-tightness. Lead 7b is electrically connected to the other electrode of nitride semiconductor laser element 5 via wire 9. A photodiode for receiving laser light emitted from the rear facet of nitride semiconductor laser element 5 may also be provided.

Cylindrical cap 3 composed of kovar (54% Fe-29% Ni-17% Co alloy) and having opening 3a is joined to stem 2. Cap glass 6 is attached at the area corresponding to opening 3a of cap 3. Cap glass 6 has a function to bring out a laser beam emitted from nitride semiconductor laser element 5 to outside of package 1. Area 1a in which nitride semiconductor laser element 5 is mounted is air-tightly sealed within package 1 by cap glass 6 and cap 3. Stem 2 is one example of a “support part” of the present invention and nitride semiconductor laser element 5 is one example of a “semiconductor laser element” of the present invention.

In this embodiment, Ni/Au metal plating is formed on the surface of stem 2 as an oxidation resistant layer, and Ni metal platings are formed on the inner and outer surfaces of cap 3 as oxidation resistant layers. Since cap 3 and stem 2 are welded together, the joint portion of cap 3 and stem 2 is formed with welding part 10. Area 1a within package 1 in which nitride semiconductor laser element 5 is mounted is filled with air having water concentration of less than 5000 ppm and oxygen concentration of more than 5% and is air-tightly sealed.

At the front facet which is light emitting face 5a, as shown in FIG. 3, nitride semiconductor laser element 5 is formed with dielectric layer 5b composed of SiO₂ which has a thickness of about 105 nm and a reflectivity of about 10%. At the rear facet that is opposite light emitting face 5a of nitride semiconductor laser element 5, dielectric layer 5c having a reflectivity of about 98% which is composed of five SiO₂ layers 5d of an about 70 nm thickness and five TiO₂ layers 5e of an about 43 nm thickness that are alternately layered from the rear facet side.

In this embodiment, the nitride semiconductor laser element 5 is formed with the dielectric layer 5b of oxide at light emitting face 5a, and the atmosphere within the package 1 in which nitride semiconductor laser element 5 is air-tightly sealed is an oxygen-containing atmosphere having oxygen concentration of more than 5%. Thus, according to the present invention, detachment of oxygen from oxide dielectric layer 5b due to low oxygen concentration of less than 5% in the atmosphere within package 1 can be suppressed. Therefore, water absorption and water adsorption by dielectric layer 5b caused at an accelerated rate by such detachment of oxygen from the dielectric layer can be suppressed. Moreover, by setting the atmospheric water concentration to be less than 5,000 ppm, water absorption and water adsorption by the dielectric layer can be even more effectively suppressed. As a result, deterioration of characteristics of semiconductor laser element 5 can be prevented and reliability of semiconductor laser device 20 can increase because detachment of oxygen from dielectric layer 5b and water absorption and water adsorption by dielectric layer 5b can be repressed. Although in this embodiment dielectric layers 5b and 5c are formed on light emitting face 5a of the cavity of nitride semiconductor laser element 5 and its rear facet respectively, the present invention is not limited to these examples, and a dielectric layer can be formed only on the rear facet of the cavity of the semiconductor laser element. Such semiconductor laser element may be used for a low output device and can achieve similar effect as the embodiment described above.

In this embodiment, Ni/Au metal plating is formed on the surface of stem 2 and Ni metal plating is formed on the inner surface of cap 3, both of which function as oxidation resistance layers and suppress oxidation of stem 2 and the interior surface of cap 3. Thus, the oxygen concentration within package 1 can be prevented from going down from the oxidation on stem 2 and the interior surface of cap 3, and detachment of oxygen from oxide dielectric layer 5b can be effectively suppressed. As a result, water absorption and water adsorption by the dielectric layer which could occur at an accelerated pace by such detachment of oxygen can be even more effectively suppressed, and deterioration of properties of dielectric layer 5b caused by such detachment of oxygen, water absorption and water adsorption can be prevented. As a result, nitride semiconductor laser device 20 has an improved reliability. In addition to the surface of stem 2 and the inner surface of cap 3, an oxidation resistant coat may also be formed such as by Ni/Au plating on surfaces of other parts exposed within package 1 such as heat release part 2a, to even more effectively suppress the decreasing of oxygen within the package 1.

In this embodiment, package 1 in which nitride semiconductor laser element 5 is housed can be easily airtight-sealed by forming welding part 10 at the joint part of cap 3 and stem 2, and thereby easily maintaining the air-tightness of the joint part of cap 3 and stem 2. Therefore, intrusion of moisture into package 1 from outside can even more effectively prevented, and thus deterioration of dielectric layer 5b can be effectively prevented.

(Manufacturing Method of the Semiconductor Device)

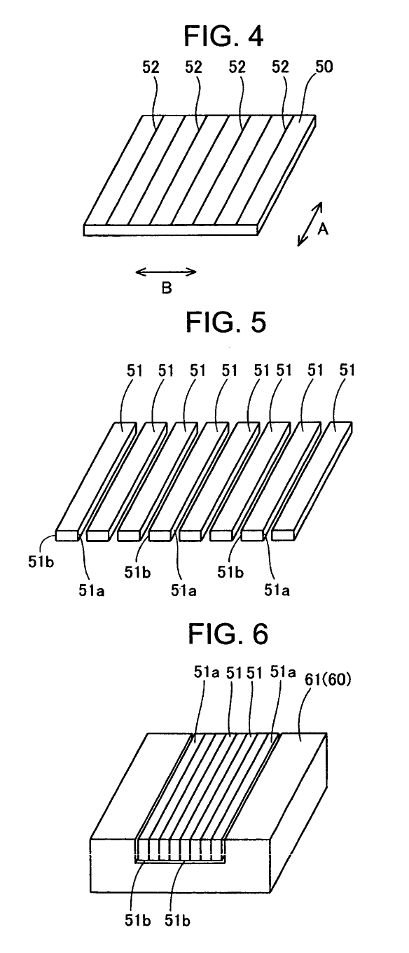

FIGS. 4 to 9 are self explanatory views that show a manufacturing method of the nitride semiconductor laser device according to the embodiment of FIG. 1. Now, referring to FIGS. 1, 2 and 4-9, the manufacturing method of the nitride semiconductor laser device 20 according to this embodiment will be described.

First, wafer 50 as shown in FIG. 4 is cleaved along a direction (arrow A direction) that is perpendicular to the direction that a stripe-shaped ridge part (electricity pathway part) (not shown) extends (arrow B direction), to form a plurality of bar-shaped wafers 51 as shown in FIG. 5. In particular, first, grooves for cleaving 52 that extend in the direction of arrow A are formed on a surface opposite the surface of the ridge part of wafer 50, as shown in FIG. 4. These grooves for cleaving 52 may be formed to continuously extend from one end to the other end in the arrow A direction of wafer 50, or may be formed in broken lines that extend from one end to the other end in the arrow A direction of wafer 50. Alternatively, grooves for cleaving 52 may be formed only near the one end and the other end in the arrow A direction of the wafer. Grooves for cleaving 52 may instead be formed on the ridge part side surface of wafer 50. In this case, grooves for cleaving 52 may be formed in broken lines that extend from one end to the other end in the arrow A direction except for the neighborhood of the ridge part that extend in the arrow B direction, or only near the one end and the other end in the arrow A direction of wafer 50. A plurality of such groves for cleaving 52 are formed at certain intervals in the arrow B direction. Grooves for cleaving 52 are formed such as by using a diamond point, laser beam, or etching. Then, the plurality of bar-shaped wafers 51 as shown in FIG. 5 are formed by cleaving along grooves 52 by using tools such as a roller and a blade jig. These cleavage faces of bar-shaped wafers 51 are used as front facet (light emitting face) 51a and rear facet 51b.

Next, as shown in FIG. 6, the plurality of bar-shaped wafers 51 are arranged onto support mounting 61 of plasma generation device 60 such that front facets (the light emitting faces) 51a are placed upward. As plasma generation device 60, for example an ECR (Electron Cyclotron Resonance) plasma generation device may be used. By generating ECR plasma while introducing an inert gas such as nitrogen gas, argon gas and helium gas inside plasma generation device 60, front facet 51a of bar-shaped wafers 51 are being cleaned. In this embodiment, cleaning was performed under the conditions of microwave output of about 500 W and nitrogen gas pressure of about 5×10⁻² Pa in the ECR plasma in the nitrogen gas atmosphere for five minutes. After this, in the same plasma generation device 60, a dielectric layer composed of SiO₂ having a thickness of about 105 nm is formed on front facet 51a of bar-shaped wafers 51 by generating ECR plasma while introducing argon gas and oxygen gas. As such, in this embodiment, cleaning of front facets 51a of bar-shaped wafers 51 and formation of the dielectric layers are continuously performed using the same plasma generation device 60.

Next, at rear facet 51b of the plurality of bar-shaped wafers 51, dielectric layers are formed by alternately layering a SiO₂ layer and a TiO₂ layer by a method such as magnetron sputtering or EB deposition. Alternatively, rear facet 51b of the plurality of bar-shaped wafer 51 may be cleaned and formed with a dielectric layer using plasma generation device 60.

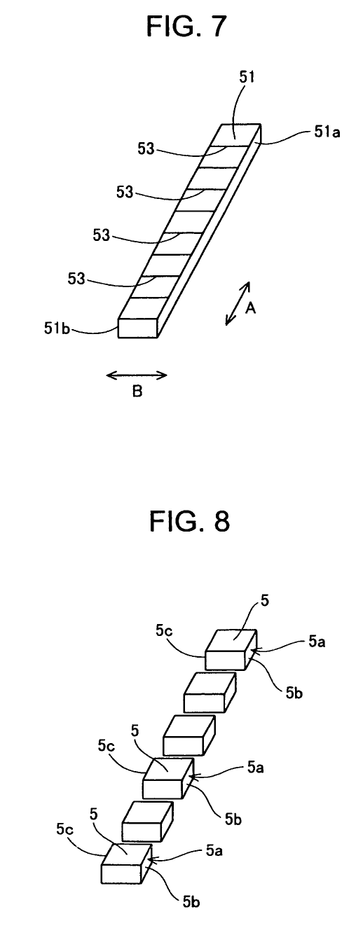

Next, a plurality of nitride semiconductor laser elements 5 as shown in FIG. 8 are formed by splitting bar-shaped wafer 51 as shown in FIG. 7 along the direction where the ridge part extends (the arrow B direction). In particular, as shown in FIG. 7, grooves for separation 53 that extend in the arrow B direction are first formed either on the surface opposite from the ridge part side of bar-shaped wafer 51 or on the surface of the ridge part side, in such a way that the areas where the ridge part is formed are positioned between each groove for separation 53. These grooves for separation 53 may be formed to continuously extend from one end to the other end in the arrow B direction of wafer 51, or may be formed in broken lines that extend from one end to the other end in the arrow B direction of wafer 51. Alternatively, grooves for separation 53 may be formed only near the one end and the other end in the arrow B direction of wafer 51. A plurality of such grooves for separation 53 are formed at certain intervals in the arrow A direction for each ridge part. Grooves for separation 53 are formed such as by using a diamond point, laser beam, or etching. Then, the nitride semiconductor laser elements as shown in FIG. 8 are formed by separating along grooves 53 by using tools such as a roller and a blade jig.

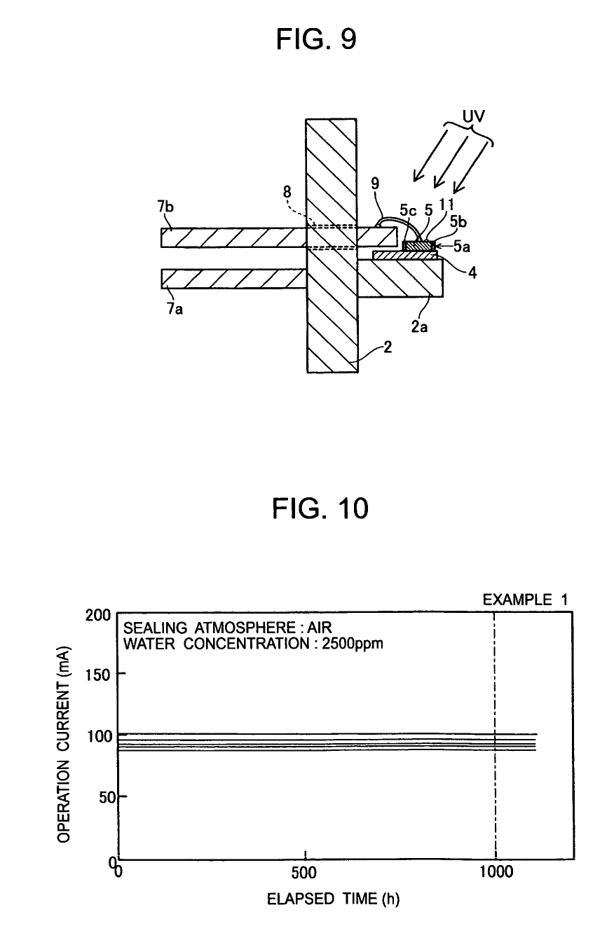

Next, as shown in FIG. 9, heat sink (submount) 4 is attached onto heat release part 2a of stem 2, which is electrically connected to lead 7a by AuSn solder, and one electrode of nitride semiconductor laser element 5 (not shown) is attached onto heat sink 4 by AuSn solder. Further, an electrode on heat sink 4 (not shown) and heat release part 2a are connected by a wire (not shown), thereby electrically connecting nitride semiconductor laser element 5 and lead 7a. Here, nitride semiconductor laser element 5 is positioned such that its light emitting face 5a comes at the opposite side from the stem 2 side. Then, the other electrode of nitride semiconductor laser element 5 (not shown) is connected with one end of wire 9 and lead 7b is connected to the other end of wire 9. As such, nitride semiconductor laser element 5 and lead 7b are electrically connected. After this, the whole stem 2 on which nitride semiconductor laser element 5 has been mounted is exposed with UV light for about 30 minutes. This process removes extraneous substance 11 attached to the upper face of nitride semiconductor laser element 5 by photodecomposition.

The whole stem 2 to which nitride semiconductor laser element 5 has been mounted is then heat treated under about 200° C. for about 1 hour in a baking furnace (not shown). At this time, cap 3 is also heat treated in the same baking furnace under about 200° C. for about 1 hour. Then, cap 3 is welded to stem 2 as shown in FIG. 2 in air (oxygen percentage of about 20%) with water concentration of less than 5000 ppm. Thus, the atmosphere within package 1 is air-tightly sealed to have the oxygen atmosphere with water concentration of less than 5000 ppm within package 1. Nitride semiconductor laser device 20 as shown in FIG. 1 is thus produced.

In this embodiment, stem 2 to which nitride semiconductor laser element 5 has been mounted is heat treated in the baking furnace before cap 3 is welded to stem 2. By this heat treatment, any moisture contained in nitride semiconductor laser element 5 and stem 2 evaporates, thus preventing problems such that water concentration of the atmosphere within the package may exceed 5000 ppm due to such evaporation of the moisture contained in nitride semiconductor laser element 5 and stem 2 into the atmosphere within the package after the air-tight sealing.

Moreover, in this embodiment, stem 2 to which the nitride semiconductor laser element 5 has been mounted is exposed to UV light before cap 3 is welded to stem 2. Thus, even when an extraneous substance 11 is attached to nitride semiconductor laser element 5, such extraneous substance 11 attached on the upper surface of nitride semiconductor laser element 5 can be removed by photodecomposition by the UV light exposure. Therefore, moisture and organic matter contained in such extraneous substance 11 can be prevented from evaporating into the atmosphere within package 1. Preventing the increase in water concentration within package 1 can prevent deterioration of reliability (duration of life) of nitride semiconductor laser device 20 caused by the increase of water concentration. Deterioration of laser beam output caused by formation of films can also be prevented from occurring.

Also in this embodiment, by cleaning at least front facets 51a of bar-shaped wafers 51 by ECR plasma, the front facets 51 of the bar-shaped wafers 51 can be cleaned by generating low energy plasma without damaging the front facets 51a. Thus, removing the oxide and contamination attached to the front facets 51a of the bar-shaped wafers 51 can prevent light absorption at front facets 51a. As a result, deterioration of a COD (Catastrophic Optical Damage) level of nitride semiconductor laser element 5 can be prevented, providing high output of nitride semiconductor laser device 20.

Also in this embodiment, cleaning of front facets 51a of bar-shaped wafers 51 and formation of the SiO₂ dielectric layers are continuously performed. Thus, contamination of front facets 51a of bar-shaped wafers 51 from exposure to air after cleaning can be prevented.

By generating ECR plasma while introducing an inert gas such as a nitrogen gas, an argon gas and a helium gas, front facets 51a of bar-shaped wafers 51 are cleaned. Thus, oxide and contamination attached to front facets 51a of bar-shaped wafers 51 can be effectively removed. For the nitride semiconductor laser element, the plasma cleaning atmosphere is preferably a nitrogen gas. This is because detachment of nitrogen from the surface of front facets 51a during cleaning can be prevented by using the same element N as the one that constructs the semiconductor laser element in cleaning.

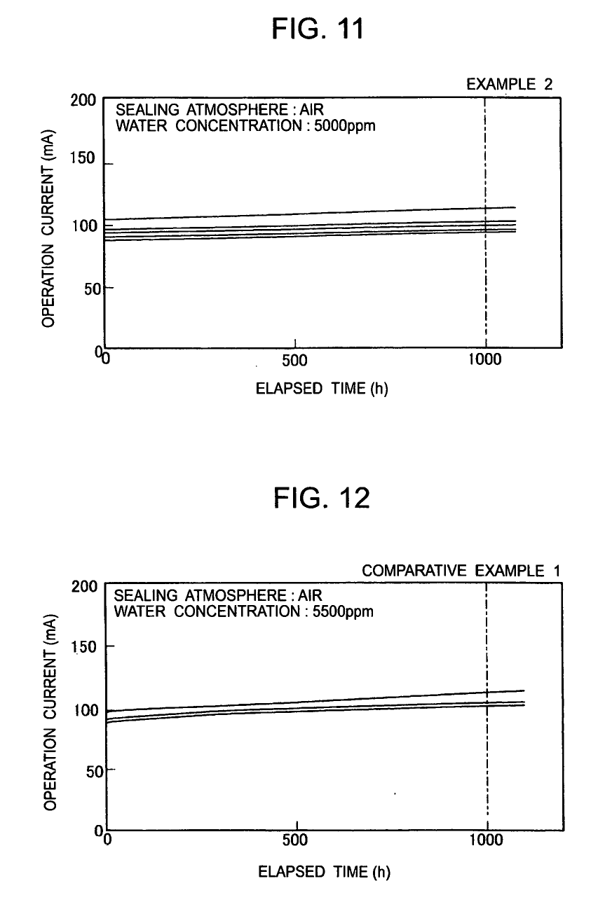

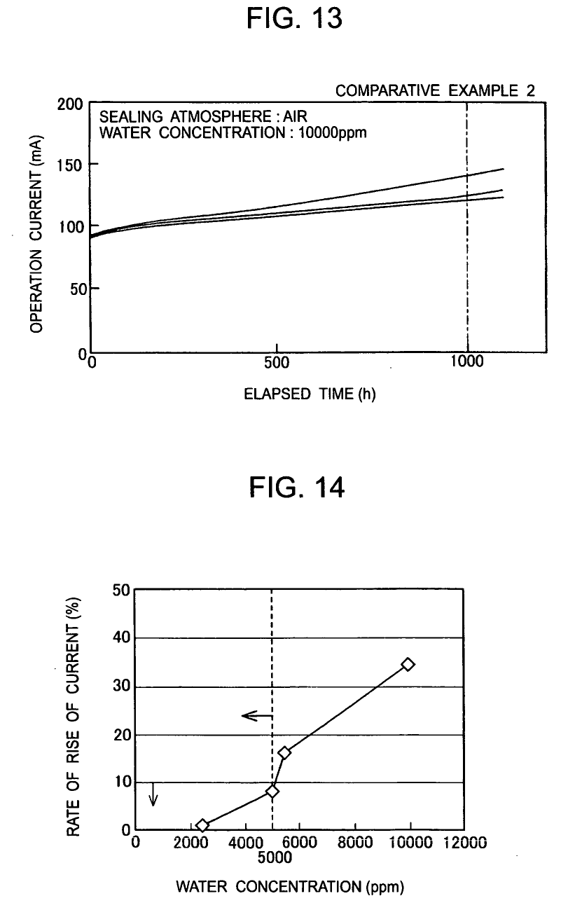

Next, an experiment performed in order to confirm the effect of this embodiment will be described. In this experiment, variation of operation current with time was measured by varying water concentration in the atmosphere within the package in order to confirm an influence of the water concentration to nitride semiconductor laser device 20 containing a dielectric layer. FIGS. 10 and 11 are correlation diagrams showing the relation between operating current of the nitride semiconductor laser device according to examples 1 and 2 respectively corresponding to the embodiment of FIG. 1 and elapsed time. FIGS. 12 and 13 are correlation diagrams showing the relation between operating current of the nitride semiconductor laser devices according to comparative examples 1 and 2 respectively and elapsed time. The horizontal axis of the correlation diagrams of FIGS. 10 to 13 shows elapsed time (h). The vertical axis of the correlation diagrams of FIGS. 10 to 13 shows operating current (mA). More specifically, FIGS. 10 to 13 show the variation of operating current with time when the nitride semiconductor laser device is operated. Except for water concentration, all of examples 1 and 2 and comparative examples 1 and 2 had the same conditions. More specifically, for all examples, a nitride semiconductor laser element was used and the atmosphere within the package was set to be air. The water concentration was set to be 2500 ppm in example 1 (FIG. 10), 5000 ppm in example 2 (FIG. 11), 5500 ppm in comparative example 1 (FIG. 12) and 10000 ppm in comparative example 2 (FIG. 13) respectively. In examples 1 and 2, respectively five nitride semiconductor laser devices were produced to perform the measurements for each nitride semiconductor laser device, and in comparative examples 1 and 2, respectively three nitride semiconductor laser devices were produced to perform the measurements for each nitride semiconductor laser device.

The measurement of the water concentration was performed using a quadrupole mass spectrometer (Model number: QMG421C) by Balzers (Germany). The quadrupole mass spectrometer has a sample chamber and a hole-forming device and so on. After a nitride semiconductor laser device was inserted within the sample chamber, inside the sample chamber was vacuumized and a hole was made by the hole-forming device on the nitride semiconductor laser device to cause the gas within the package to be released. Then, the gas released to the quadrupole mass spectrometer was introduced to measure its water concentration.

From the measurement results as shown in FIGS. 10 to 13, it was confirmed that the operation current values after 1000 hours tend to increase as the water concentration increases. More particularly, with the nitride semiconductor laser device of example 1, which has water concentration of 2500 ppm, almost no increase of the operation current values after 1000 hours was confirmed as shown in FIG. 10. With the nitride semiconductor laser device of example 2, which has water concentration of 5000 ppm, only a small increase of the operation current values occurred after 1000 hours as shown in FIG. 11. On the other hand, as shown in FIG. 12, it became clear that with the nitride semiconductor laser device of comparative example 1 having water concentration of 5500 ppm, the degree of increase of the operation current values after 1000 hours is larger in comparison with the nitride semiconductor laser device of example 2 (FIG. 11) having water concentration of 5000 ppm. Moreover, with the nitride semiconductor laser device of comparative example 2, which has water concentration of 10000 ppm, as shown in FIG. 13, it became clear that the degree of increase of the operation current values after 1000 hours is even larger compared with the comparative example 1 (FIG. 12).

FIG. 14 is a correlation diagram showing the relation between the water concentration of the nitride semiconductor laser device and the rate of current rise. To be more precise, the rate of current rise (%) was calculated based on the results of FIGS. 10 to 13 and the relation between the calculated rate of current rise and the water concentration was shown. For each measurement, the difference between the operation current right after operating the nitride semiconductor laser element and the operation current after 1000 hours is shown in percentage and the average amount of the measurements for each water concentration was shown as the rate of current rise (%) in FIG. 14. The allowable range for the rate of current rise (%) was set as being less than 10%.

From the measurement results as shown in FIG. 14, it was found that when the water concentration within the package of the nitride semiconductor laser device is less than 5000 ppm, the rate of current rise stayed in the allowable range of less than 10%, and that when the water concentration increased from 5000 ppm to 5500 ppm, the rate of current rise rapidly increased. This is thought to be due to the following reason. When the water concentration exceeds 5000 ppm, water absorption and water adsorption occur at the dielectric layer formed on the light emitting face of the nitride semiconductor laser element, which accelerates deterioration of the dielectric layer and deterioration of the nitride semiconductor laser element, which causes the rate of current rise to increase. From the measurement results of FIG. 14, it was confirmed that life duration of the nitride semiconductor laser device can increase by forming the dielectric layer with oxide (SiO₂), setting the atmosphere within the package to be air atmosphere (oxygen concentration of about 20%), and keeping the water concentration within the package to be less than 5000 ppm, which improves the reliability.

Next, an experiment for confirming detachment of oxygen from the dielectric layer of the nitride semiconductor laser element will be described. In this experiment, the dielectric layer formed on the light emitting face of the nitride semiconductor laser element from nitride semiconductor laser devices having varying water and oxygen concentrations was observed. The observation of the dielectric layer was made by operating the nitride semiconductor laser device with an output of 50 mW for about 100 hours and then visually observing the change of color of the dielectric layer using an optical microscope. For the oxygen concentration, six conditions of 0%, 2%, 5%, 10%, 20% and 30% were used, and for the water concentration, three conditions of 2500 ppm, 5000 ppm and 10000 ppm were used. Because the color of the dielectric layer changes due to the detachment of oxygen from the dielectric layer formed on the light emitting face of the nitride semiconductor laser element, it was determined that the oxygen detachment occurred by the change of color in the dielectric layer. In this observation, only the observation of the dielectric layer formed at the front facet (light emitting face) of the nitride semiconductor laser element was performed to see whether or not the color has changed. The measurement of oxygen concentration within the package of the nitride semiconductor laser device was performed by a method similar to the measurement of the water concentration described above. The results are shown in Table 1 below.

TABLE 1

| | | Oxygen Concentration (%) | | | | | |
|---|---|---|---|---|---|---|---|
| | | 0 | 2 | 5 | 10 | 20 | 30 |
| Water | 2500 | X | X | ◯ | ◯ | ◯ | ◯ |
| Concentration | 5000 | X | X | ◯ | ◯ | ◯ | ◯ |
| (ppm) | 10000 | X | X | Δ | Δ | Δ | Δ |

◯: no change of color, Δ: no change of color (change of properties), X: presence of change of color

A circle mark in above Table 1 shows that there was no change of color on the dielectric layer formed on the light emitting face of the nitride semiconductor laser element. An X mark shows that there was a change of color on the dielectric layer. A triangle mark shows that even though there was no change of color on the dielectric layer, it is regarded that there was a change of properties of the dielectric layer because of the high rate of current rise according to the result of FIG. 13 above.

As shown in Table 1, in any of the water concentration conditions, change of color on the dielectric layer was not confirmed at the oxygen concentration of more than 5% according to the visual observation by optical microscope. Therefore, it was confirmed that detachment of oxygen from the dielectric layer can be prevented by setting the oxygen concentration in the atmosphere within the package to be more than 5%. Although no change of color on the dielectric layer was confirmed with the oxygen concentration of more than 5% for the nitride semiconductor laser device having water concentration 10000 ppm, it is regarded that the properties of the dielectric layer changed because the current rise was prominent. Therefore, according to the results as shown in Table 1, preventing deterioration of the dielectric layer formed at the light emitting face of the nitride semiconductor laser element is believed to require a package atmosphere to be an oxygen-containing atmosphere of more than 5% oxygen concentration and less than 5000 ppm water concentration.

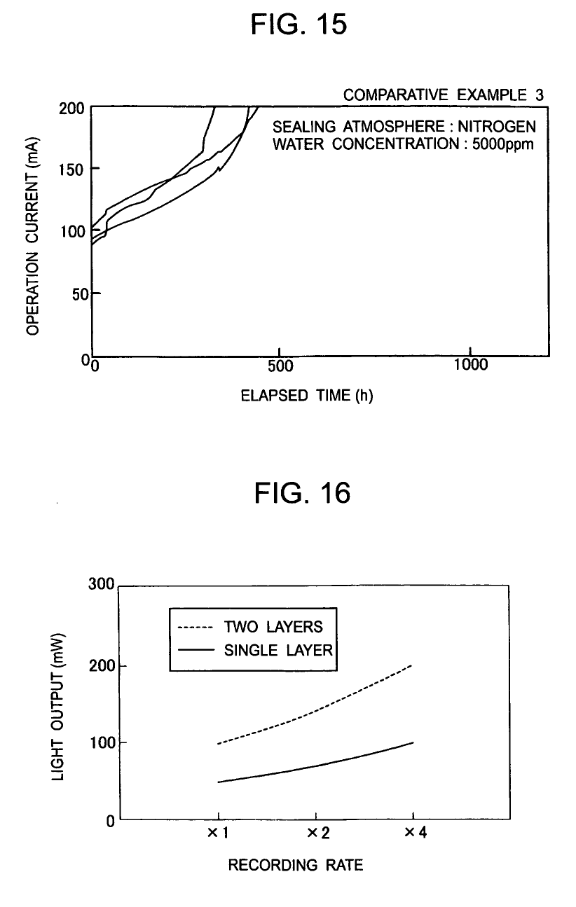

Next, an experiment for confirming an influence of detachment of oxygen from the dielectric layer formed at the light emitting face of the nitride semiconductor laser element will be described. In this experiment, a nitride semiconductor laser device was produced to have a nitrogen atmosphere within the package that does not contain any oxygen and water concentration of 5000 ppm, and its variation of operation current with time was measured. FIG. 15 is a correlation diagram showing the relation between the operating current of the nitride semiconductor laser device according to comparative example 3 and elapsed time. The horizontal axis of the correlation diagram shows elapsed time (h) similar to FIGS. 10 to 13. The vertical axis of the correlation diagram shows operating current (mA) similar to FIGS. 10 to 13. In FIG. 15, because the sealing atmosphere is nitrogen (oxygen concentration of 0%), according to the results of Table 1, it is thought that detachment of oxygen from the dielectric layer occurred.

According to the measurement results shown in FIG. 15, it became clear that when nitrogen is used for the sealing atmosphere, the degree of operation current rise with time was extremely large compared with when the sealing atmosphere was air (oxygen percentage of approximately 20%) as shown in FIGS. 10 to 13. Accordingly, it was confirmed that reliability of a nitrogen semiconductor laser device notably deteriorates when there is a large amount of oxygen detachment from the dielectric layer when the sealing atmosphere is a nitrogen atmosphere containing no oxygen.

Next, an experiment was performed to confirm a relation between a lasing wavelength and a light output power when the atmosphere within the package is a nitrogen atmosphere containing no oxygen. In this experiment, semiconductor laser devices that emit laser beam of varying lasing wavelengths were produced with the atmosphere within the package being a nitrogen atmosphere containing no oxygen, and detachment of oxygen from the dielectric layer was observed under the varying light outputs. The observation method was similar to above Table 1. More specifically, color change of the dielectric layer was visually observed by optical microscopy after operating the semiconductor laser devices for about 100 hours. The results are shown in Table 2.

TABLE 2
Sealing atmosphere: N2

| | | Lasing Wavelength (nm) | | |
|---|---|---|---|---|
| | | 405 | 650 | 780 |
| Light Output | 5 | X | ◯ | ◯ |
| (mW) | 10 | X | ◯ | ◯ |
| | 30 | X | X | ◯ |
| | 50 | X | X | ◯ |

◯: no change of color, X: presence of change of color

As shown in the above Table 2, three conditions of 405 nm, 650 nm and 780 nm were used for the lasing wavelength and four conditions were used for the light output. The water concentration within the package was 5000 ppm for each semiconductor laser device in this experiment. A circle mark in Table 2 shows that there was no change of color on the dielectric layer. An X mark shows that there was a change of color on the dielectric layer. As shown in Table 2, it was confirmed that when the atmosphere within the package is a nitrogen atmosphere containing no oxygen, change of color on the dielectric layer was confirmed in a nitride semiconductor laser device that emits a blue-violet laser beam with a wavelength of 405 nm, which reveals oxygen detachment. When the atmosphere within the package is a nitrogen atmosphere containing no oxygen, in a semiconductor laser device that emits a red laser beam with a wavelength of 650 nm, no change of color on the dielectric layer was confirmed when the light output was low (5 mW and 10 mW), showing no oxygen detachment, while change of color was confirmed when the light output was high (30 mW and 50 mW), showing occurrence of oxygen detachment from the dielectric layer. Also, when the atmosphere within the package is a nitrogen atmosphere containing no oxygen, in a semiconductor laser device that emits an infrared laser beam with a wavelength of 780 nm, no change of color was confirmed in any of the light outputs (5 mW, 10 mW, 30 mW and 50 mW), showing no oxygen detachment from the dielectric layer.

From these results, it was confirmed that when a nitride semiconductor laser element that emits a blue-violet laser beam with a wavelength of 405 nm is used as a semiconductor laser element, even when the light output is low such as 5 mW, detachment of oxygen from the dielectric layer occurs when the oxygen concentration within the package is 0% (nitrogen atmosphere). Thus, it can be seen that the nitride semiconductor laser element that emits blue-violet laser beam with a wavelength of 405 nm is more prone to oxygen detachment compared to the semiconductor laser device that emits a red laser beam with a wavelength of 650 nm or the semiconductor laser device that emits an infrared laser beam with a wavelength of 780 nm. This is considered to be due to the fact that the blue-violet laser beam with a wavelength of 405 nm emitted from the nitride semiconductor laser element has a larger light energy compared with the red laser beam with a wavelength of 650 nm or the infrared laser beam with a wavelength of 780 nm. Therefore, it is regarded that setting the atmosphere within the package to be an oxygen atmosphere having water concentration of less than 5000 ppm and oxygen concentration of more than 5% is particularly effective for a nitride semiconductor laser device in order to prevent detachment of oxygen from the dielectric layer composed of oxide, as described in this embodiment.

Now, characteristic features required for a semiconductor laser element will be explained. In recent years, improvements of recording rate and recording capacity have been required in recording data in an optical disk. In order to improve the recording rate, shortening the data recording time into the optical disk is required. In order to improve the recording capacity, multi-layering is required. In either case, higher output of the semiconductor laser element as a light source is necessary. FIG. 16 is a graph showing an example of the relation between the recording rate and the light output of a semiconductor laser element when the semiconductor laser element that outputs blue-violet laser beam is used as a light source. FIG. 16 shows that about 200 mW light output is required for recording data into an optical disk in two layers and at quad-speed, in order to improve recording rate and recording capacity. Also, in order to obtain a light output of about 200 mW from a semiconductor laser element, about 250 mW to 300 mW COD (Catastrophic Optical Damage) level is required.

Next, an experiment was performed for confirming an effect of cleaning the front facet (light emitting face) and rear facet of a nitride semiconductor laser element by ECR plasma before forming a dielectric layer. In order to confirm an effect of the ECR plasma cleaning, in this experiment, a nitride semiconductor laser device according to example 3 in which both the front and rear facets of the nitride semiconductor laser element were cleaned, a nitride semiconductor laser device according to example 4 in which only the front facet of the nitride semiconductor laser element was cleaned, and a nitride semiconductor laser device according to example 5 in which neither the front facet nor the rear facet was cleaned were respectively produced. The atmosphere within the package was air with water concentration of 5000 ppm in each example. Before the cap was welded onto the stem, a UV light was applied for about 30 minutes.

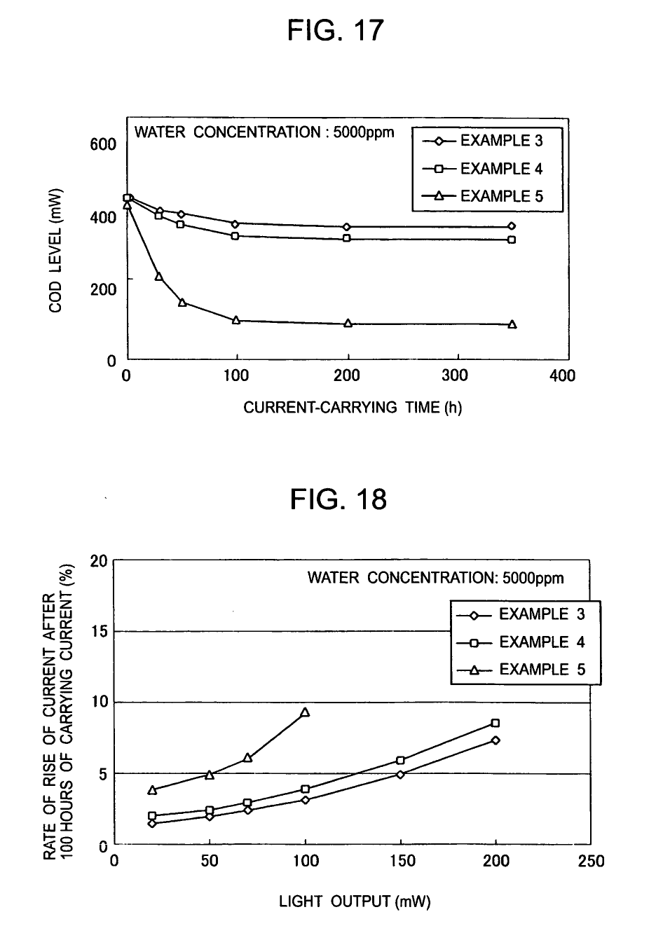

First, current was applied to the produced nitride semiconductor laser devices of examples 3 to 5 for 350 hours under the conditions of light output of 60 mW, package temperature of 70° C., and water concentration of the atmosphere within the package of 5000 ppm, and the COD levels for examples 3 to 5 were measured. The result of the measurement is shown in FIG. 17. According to the measurement result as shown in FIG. 17, both the nitride semiconductor laser device of example 3 in which both the front and rear facets of the nitride semiconductor laser element were cleaned, and the nitride semiconductor laser device of example 4 in which only the front facet of the nitride semiconductor laser element was cleaned, had the COD level of more than 300 mW after current was applied for 350 hours. Example 3 in which both the front and rear facets of the nitride semiconductor laser element were cleaned had a somewhat higher COD level than example 4 in which only the front facet of the nitride semiconductor laser element was cleaned. On the other hand, the COD level of example 5 in which neither the front facet nor the rear facet was cleaned was less than 100 mW after 350 hours of applying current. Thus, it is believed that deterioration of the COD level can be prevented by ECR plasma cleaning via preventing light absorption at the front and rear facets by removing oxide and contamination from the front facet or rear facet of the nitride semiconductor laser element.

Next, for the produced nitride semiconductor laser devices of examples 3 to 5, current was applied for 100 hours under the conditions of light outputs 20 mW to 200 mW, package temperature of 70° C., and water concentration of the atmosphere within the package of 5000 ppm, and rate of current rise after 100 hours of applying the current was measured for each light output value. The measurement results are shown in FIG. 18. From the measurement result as shown in FIG. 18, both the nitride semiconductor laser device of example 3 in which both the front and rear facets of the nitride semiconductor laser element were cleaned, and the nitride semiconductor laser device of example 4 in which only the front facet of the nitride semiconductor laser element was cleaned had the rate of current rise of less than 10% at the light output of 200 mW after 100 hours of applying current. Also, example 3 in which both the front and rear facets of the nitride semiconductor laser element were cleaned had a somewhat lower rate of current rise than example 4 in which only the front facet of the nitride semiconductor laser element was cleaned. On the other hand, in the nitride semiconductor laser device of example 5 in which neither the front facet nor the rear facet was cleaned, the nitride semiconductor laser element was damaged by COD after 100 hours at light output of 150 mW. Thus, it is believed that by preventing deterioration of the COD level of the nitride semiconductor laser element, a higher-power nitride semiconductor laser device can be obtained. It is believed that when the atmosphere within the package has water concentration of 5000 ppm, when using the nitride semiconductor laser device of example 3 and 4 in which at least the front facet of the nitride semiconductor laser element is cleaned by ECR plasma, one can produce an optical disk device capable of recording data in the optical disk in two layers and at quad-speed which requires a light output of about 200 mW.

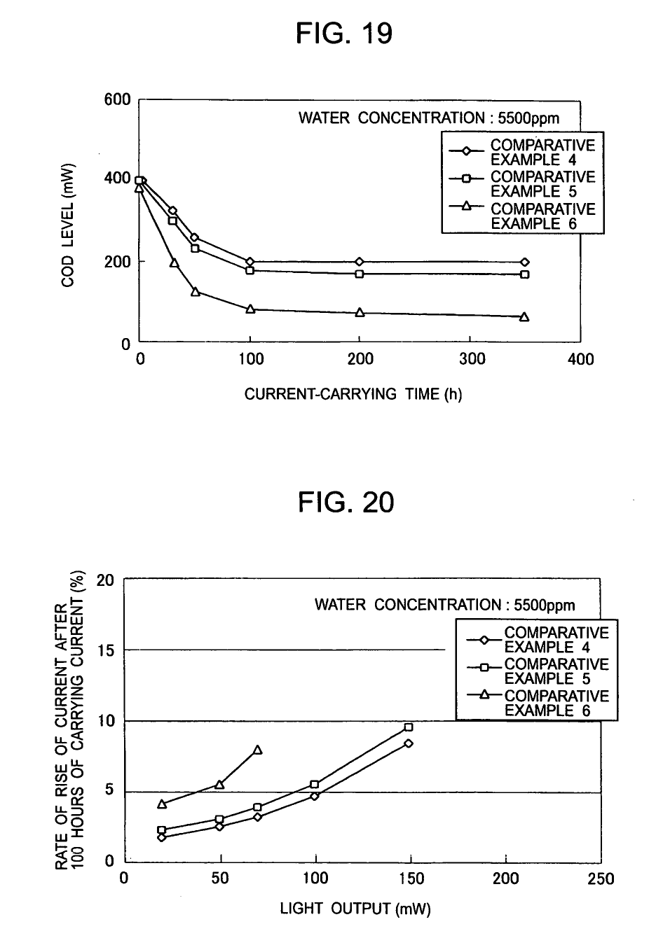

Next, an experiment for confirming an influence of cleaning of the front and rear facets of the nitride semiconductor laser element and water concentration of the atmosphere within the package will be explained. In this experiment, unlike the nitride semiconductor laser device of above examples 3 to 5, nitride semiconductor laser devices of comparative examples 4 to 6 having water concentration of the atmosphere within the package of 5500 ppm were produced. The conditions in producing nitride semiconductor laser devices of comparative examples 4 to 6 were the same as the nitride semiconductor laser devices of examples 3 to 5 respectively, except for the water concentration. For the produced nitride semiconductor laser devices of comparative examples 4 to 6, current was applied for 350 hours under the conditions of light output of 60 mW, package temperature of 70° C., and water concentration of the atmosphere within the package of 5500 ppm, and the COD levels for comparative examples 4 to 6 were measured. The measurement results are shown in FIG. 19. According to the measurement results as shown in FIG. 19, the COD levels of comparative examples 4 to 6 were all less than 200 mW after 100 hours of applying current. Comparative example 4 in which both the front and rear facets of the nitride semiconductor laser element were cleaned had a somewhat higher COD level than comparative example 5 in which only the front facet of the nitride semiconductor laser element was cleaned. The COD level of comparative example 6 in which neither the front facet nor the rear facet was cleaned was lower than the COD level of comparative example 5 in which only the front facet of the nitride semiconductor laser element was cleaned. Thus, it is believed that even when the oxide and contamination at the front and rear facets of the nitride semiconductor laser element are removed by the ECR plasma cleaning, due to the water concentration of the atmosphere within the package being higher than 5000 ppm, water absorption and water adsorption by the dielectric layer occur and light is absorbed at the front and rear facets, which deteriorates the COD level.

Next, for the produced nitride semiconductor laser devices of comparative examples 4 to 6, current was applied for 100 hours under the conditions of light outputs 20 mW to 200 mW, package temperature of 70° C., and water concentration of the atmosphere within the package of 5500 ppm, and rate of current rise after 100 hours of applying the current was measured for each light output value. The measurement results are shown in FIG. 20. From the measurement result as shown in FIG. 20, in the nitride semiconductor laser device of comparative example 4 in which both the front and rear facets of the nitride semiconductor laser element were cleaned, and the nitride semiconductor laser device of comparative example 5 in which only the front facet of the nitride semiconductor laser element was cleaned, the nitride semiconductor laser elements were damaged by COD at the light output of 200 mW after 100 hours of applying current. In the nitride semiconductor laser device of comparative example 6 in which neither the front facet nor the rear facet was cleaned, the nitride semiconductor laser element was damaged by COD after 100 hours at light output of 100 mW. Thus, it is believed that when the water concentration within the package exceeds 5000 ppm, regardless of cleaning treatment by ECR plasma, it is difficult to obtain a high power nitride semiconductor laser device because of the low COD level of the nitride semiconductor laser element. Thus, it is believed that the cleaning processing by the ECR plasma effectively functions in a condition of water concentration within the package being less than 5000 ppm.

The present invention may be embodied in other specific forms without departing from the spirit or essential characteristics thereof. The embodiments are therefore to be considered in all respects as illustrative and not restrictive, the scope of the present invention being indicated by the appended claims rather than by the foregoing description, and all changes that come within the meaning and range of equivalency of the claims are therefore intended to be embraced therein.

For example, the above embodiment showed an example of applying the invention for a nitride semiconductor laser element as an example of the semiconductor laser element. However, the present invention may be used for a semiconductor laser element other than a nitride semiconductor laser element.

In the above embodiment, the dielectric layers composed of oxide 5b and 5c were formed on the front facet of light emitting face 5a and the rear facet opposite light emitting face 5a respectively. However, a dielectric layer composed of oxide may be formed either on the front facet that is the light emitting race or the rear facet opposite the light emitting face.

Although AlN was used for the heat sink (submount) in the example of the above embodiment, the heat sink (submount) can be formed by using materials other than AlN. As the material other than AlN, for example, materials such as SiC, diamond, Si, Cu, Al, or CuW may be used.

The above embodiment showed an example in which a stem made of iron was welded with a cap made of kovar (54% Fe-29% Ni-17% Co alloy). However, materials other than iron and kovar (54% Fe-29% Ni-17% Co alloy) may be used for the stem and the cap respectively.

In the above embodiment, Ni/Au metal plating was formed on the stem surface and Ni metal plating was formed on the inner and outer surfaces of the cap. However, as long as oxidization of the stem and cap surfaces can be prevented, metal platings of alloys other Ni/Au, such as Au metal plating or Ni metal plating can be formed on the stem surface, and metal plating of metals other than Ni, such as Au metal plating or Ni/Au metal plating can be formed on the inner and outer surfaces of the cap.

SiO₂ and TiO₂ were used as the dielectric layer formed on the light emitting face of the nitride semiconductor laser element in the above embodiment. However, as long as the dielectric layer is composed of oxide, materials other than SiO₂ and TiO₂ may be used. Examples of such materials other than SiO₂ and TiO₂ may be Al₂O₃, ZrO₂, Ta₂O₅, Nb₂O₅, or La₂O₃. Or oxide having different composition ratio from above metals, such as Ti₃O₅ and Nb₂O₃ may be used.

In the above embodiment, one layer of the dielectric layer was formed on the light emitting face of the nitride semiconductor laser element. However, the dielectric layer may be formed in a multi-layer structure that includes other materials on the light emitting face of the nitride semiconductor laser element.

As an atmosphere within the package, an example that uses air was used in the above embodiment. However, as long as the oxygen concentration is more than 5%, an oxygen-containing atmosphere other than air may be used. As examples of such oxygen-containing atmosphere other than air, a mixture of N₂ and O₂, or mixture of an inert gas other than nitrogen and O₂ may be used.

What is claimed is:

1. A semiconductor laser device, comprising:
a semiconductor laser element having a dielectric layer composed of oxide, the dielectric layer being formed at least on a light emitting face; and
a package within which the semiconductor laser element is air-tightly sealed;
wherein an atmosphere within the package is an oxygen-containing atmosphere having water concentration of less than 5000 ppm.

2. A semiconductor laser device, comprising:
a semiconductor laser element having a dielectric layer composed of oxide, the dielectric layer being formed only on a rear facet opposite a light emitting face; and
a package within which the semiconductor laser element is air-tightly sealed;
wherein an atmosphere within the package is an oxygen-containing atmosphere having water concentration of less than 5000 ppm.

3. The semiconductor laser device of claim 1, wherein oxygen concentration of the oxygen-containing atmosphere is more than 5%.

4. The semiconductor laser device of claim 2, wherein oxygen concentration of the oxygen-containing atmosphere is more than 5%.

5. The semiconductor laser device of claim 1, wherein the package includes a support part for supporting the semiconductor laser element, and a cap part which is joined to the support part for air-tightly sealing the semiconductor laser element therewithin; and
wherein an oxidation resistance layer is formed on a surface of the support part and on an inner surface of the cap part.

6. The semiconductor laser device of claim 2, wherein the package includes a support part for supporting the semiconductor laser element, and a cap part which is joined to the support part for air-tightly sealing the semiconductor laser element therewithin; and
wherein an oxidation resistance layer is formed on a surface of the support part and on an inner surface of the cap part.

7. The semiconductor laser device of claim 1, wherein the package includes a support part for supporting the semiconductor laser element, and a cap part which is joined to the support part for air-tightly sealing the semiconductor laser element therewithin; and
wherein a welding part is formed at a joint of the cap part and the support part.

8. The semiconductor laser device of claim 2, wherein the package includes a support part for supporting the semiconductor laser element, and a cap part which is joined to the support part for air-tightly sealing the semiconductor laser element therewithin; and
wherein a welding part is formed at a joint of the cap part and the support part.

9. The semiconductor laser device of claim 1, wherein the semiconductor laser element is a nitride semiconductor laser element.

10. The semiconductor laser device of claim 2, wherein the semiconductor laser element is a nitride semiconductor laser element.

11. A method for manufacturing a semiconductor laser device, comprising:
forming a dielectric layer composed of oxide at least on a light emitting face of a semiconductor laser element;
mounting the semiconductor laser element on a support part;
exposing the support part on which the semiconductor laser element is mounted with UV light; and
then air-tightly sealing the semiconductor laser element with a cap part in an oxygen-containing atmosphere having water concentration of less than 5000 ppm.

12. The method for manufacturing a semiconductor laser device of claim 11, wherein the process of air-tightly sealing the semiconductor laser element with the cap part is performed in an oxygen-containing atmosphere having oxygen concentration of more than 5%.

13. The method for manufacturing a semiconductor laser device of claim 11, further comprising a process of cleaning at least the light emitting face of the semiconductor laser element by plasma before forming the dielectric layer composed of oxide.

14. A method for manufacturing a semiconductor laser device, comprising:
forming a dielectric layer composed of oxide only on a rear facet opposite a light emitting face of a semiconductor laser element;
mounting the semiconductor laser element on a support part;
exposing the support part on which the semiconductor laser element is mounted with UV light; and
then air-tightly sealing the semiconductor laser element with a cap part in an oxygen-containing atmosphere having water concentration of less than 5000 ppm.

15. The method for manufacturing a semiconductor laser device of claim 14, wherein the process of air-tightly sealing the semiconductor laser element with the cap part is performed in an oxygen-containing atmosphere having oxygen concentration of more than 5%.

16. The method for manufacturing a semiconductor laser device of claim 14, further comprising a process of cleaning the rear facet opposite the light emitting face of the semiconductor laser element by plasma before forming the dielectric layer composed of oxide.

17. The method for manufacturing a semiconductor laser device of claim 13, wherein the process of cleaning by plasma is performed in an inert gas atmosphere.

18. The method for manufacturing a semiconductor laser device of claim 16, wherein the process of cleaning by plasma is performed in an inert gas atmosphere.
